(19) United States
(12) Patent Application Publication
(10) Pub. No.: US 2012/0119332 A1
(43) Pub. Date: May 17, 2012

(54) PROCESS FOR PRODUCING A SEMICONDUCTOR-ON-SAPPHIRE ARTICLE

(76) Inventor: Petar Branko Atanackovic, South Australia (AU)

(21) Appl. No.: 13/377,701

(22) PCT Filed: Jun. 11, 2010
(86) PCT No.: PCT/AU10/00721

§ 371 Date: Dec. 27, 2011

Related U.S. Application Data
(60) Provisional application No. 61/186,754, filed on Jun. 12, 2009.

(51) Int. Cl. H01L 29/32; H01L 29/161; H01L 21/322

(52) U.S. Cl. 257/616; 438/473; 257/629; 257/E21.32; 257/E29.107; 257/E29.084

(57) ABSTRACT

A process for producing a semiconductor-on-sapphire article, including: forming a barrier layer and a semiconductor layer on a sapphire substrate, the barrier layer being disposed between the sapphire substrate and the semiconductor layer to inhibit at least one of aluminium from the sapphire and extended defects arising from the sapphire-semiconductor interface from entering the semiconductor layer; wherein the semiconductor is at least one of silicon and a silicon-germanium alloy.

### TECHNICAL FIELD

The present invention relates to a semiconductor-on-sapphire article of manufacture and a process for producing a semiconductor-on-sapphire article.

### BACKGROUND

Silicon-on-insulator or ‘SOI’ wafers or substrates were developed for use in place of standard silicon wafers or substrates in the microelectronics industry for applications requiring extremely high electrical insulation between microelectronic devices fabricated in silicon. One particularly advantageous form of SOI wafer consists of a very thin layer of silicon attached to a sapphire support or substrate, and is referred to in the art as ‘silicon-on-sapphire’, or ‘SOS’. Sapphire is a single-crystal form of Al₂O₃, and its crystalline structure allows a layer of single-crystal silicon to be epitaxially grown on certain lattice planes of the sapphire surface to provide an extremely thin layer of single-crystal silicon.

Silicon on sapphire (SOS) offers several advantages over bulk silicon in microelectronic applications. First, by enabling substantially lower junction capacitance and fully depleted channel devices, it enables transistor performance that is typically 30 to 50% better than transistors of the same dimensions fabricated in bulk silicon. In addition, because SOS eliminates many current leakage paths, SOS circuits demonstrate superior radiation hardness to their bulk silicon counterparts.

However, the growth of single-crystal silicon on a sapphire substrate suffers from two major difficulties. First, under high temperature processing during the epitaxial growth of the silicon layer (and subsequent device fabrication in that layer), aluminium diffuses out of the sapphire and into the silicon. Aluminium is a p-type dopant in silicon, and the resulting unwanted doping can severely compromise the operation of electronic and/or opto-electronic devices formed in the silicon layer.

Prior approaches to fabricating silicon-on-sapphire substrates have addressed this problem by lowering the temperatures at which the silicon layer is formed and the devices are fabricated, thereby substantially reducing the diffusion of aluminium into the silicon. However, these methods require the process temperatures to be carefully controlled during the formation of the silicon layer and during the subsequent device processing steps. Moreover, although such low temperature processing reduces the diffusion of aluminium into the silicon layer, it also makes it much more difficult to grow high quality silicon films. In particular, the lattice mismatch between the sapphire surface and the silicon grown on that surface causes extended defects to form in the silicon layer.

As described in U.S. Pat. Nos. 5,895,957 and 5,600,169, this difficulty can be addressed by amorphising a sub-surface or buried portion of the silicon layer containing nearly all of thee extended defects. This is achieved by implanting the silicon layer with silicon ions under conditions that leave the topmost portion of the silicon layer (which contain only a very low density of extended defects) in single-crystal form. Thus the implantation forms a buried amorphous silicon layer that extends down to the sapphire, and is overlayed by a single-crystal silicon layer. The buried amorphous silicon layer is then epitaxially regrown using the single-crystal surface layer as a seed providing a single crystal layer substantially free of extended defects.

While this process significantly reduces the density of defects in the silicon layer, the residual defect densities are still high enough to degrade the performance and yield of microelectronic devices formed in the silicon layer, thus preventing silicon-on-sapphire technology from being scaled to smaller dimensions. For example, FIG. 1 shows a transmission electron microscope (TEM) image of a portion of a cross-section of a microelectronic device formed in silicon-on-sapphire. The image shows the sapphire substrate 102 and silicon epitaxial layer 104. It also shows an oxide layer 106 formed on top of the silicon layer 104 and a via 108 formed as part of the microelectronic structure. It also shows the interface layers 110, 112 that form between the silicon and sapphire (IL_{L} 110) and between the silicon and oxide (IL_{U} 112). As shown in the figure, the density of the residual extended defects 114 can be as high as 4.4 defects per micron in a 100 nm silicon film. This density of defects effectively limits the applications of silicon on sapphire in microelectronics to the 0.18 μm or earlier technology nodes.

These residual extended defects 114 act as recombination centres, degrading the performance of microelectronic and optoelectronic devices formed in the silicon layer 104. Moreover, the defects 114 can grow under the influence of high electrical currents during device operation, thus, for example, reducing the lifetime of light emitting diodes formed in the silicon layer. Finally, even with careful temperature control, substantial amounts of aluminium can still diffuse into the silicon layer.

It is desired to provide a semiconductor-on-sapphire article and a process for producing a semiconductor-on-sapphire article that alleviate one or more difficulties of the prior art, or at least provide a useful alternative.

### SUMMARY

Embodiments of the present invention address the limitations of the prior art by reducing the diffusion of aluminium from the sapphire layer into the semiconductor and/or by reducing the density of extended defects in the semiconductor layer.

In accordance with the present invention, there is provided a process for producing a semiconductor-on-sapphire article, including:
forming a barrier layer and a semiconductor layer on a sapphire substrate, the barrier layer being disposed between the sapphire substrate and the semiconductor layer to inhibit at least one of aluminium from the sapphire and extended defects arising from the sapphire-semiconductor interface from entering the semiconductor layer;

wherein the semiconductor is at least one of silicon and a silicon-germanium alloy.

In some embodiments, the forming includes:
forming the barrier layer on the sapphire substrate; and
forming the semiconductor layer on the barrier layer.

In other embodiments, the forming includes:
forming the semiconductor layer on the sapphire substrate; and
forming the barrier layer between the sapphire substrate and the semiconductor layer.

Also described herein is a process for producing a semiconductor-on-sapphire substrate, including:
forming a barrier layer on a sapphire substrate; and
forming a semiconductor layer on the barrier layer;
wherein the barrier layer inhibits diffusion of aluminium from the sapphire substrate into the semiconductor layer.

Also described herein is a process for producing a semiconductor-on-sapphire substrate, including:
forming a semiconductor layer on a sapphire substrate; and
forming a diffusion barrier between the sapphire substrate and the semiconductor layer to inhibit diffusion of aluminium from the sapphire substrate into the semiconductor layer.

The semiconductor layer may be a crystalline semiconductor layer.

The crystalline semiconductor layer may be a single-crystal semiconductor layer.

The single-crystal semiconductor layer may be a high quality single-crystal semiconductor layer epitaxially grown on the sapphire substrate. The epitaxial growth may be formed by molecular beam epitaxy.

The process may further include forming, on the high-quality single-crystal semiconductor layer, a further single-crystal semiconductor layer, wherein the diffusion barrier allows the further single-crystal semiconductor layer to be epitaxially grown at a relatively high temperature to improve the quality of the further single-crystal semiconductor layer without substantial aluminium diffusion from the sapphire substrate into either of the single-crystal semiconductor layers.

The further single-crystal semiconductor layer may be formed by a lower cost process than the process used to grow the initial high-quality single-crystal semiconductor layer.

The further single-crystal semiconductor layer may be formed by vapour phase epitaxy or LPCVD.

The diffusion barrier may be a compound of semiconductor and/or a compound of aluminium.

The forming of a diffusion barrier may include forming a layer of semiconductor nitride.

The forming of a diffusion barrier may include forming a layer of aluminium nitride.

The diffusion barrier may be formed by exposing the sapphire substrate to a reactive plasma.

The plasma may be a nitrogen plasma.

The forming of a diffusion barrier may include forming a layer of at least one oxide of semiconductor.

The diffusion barrier may be formed by ion implantation.

The forming of a diffusion barrier may include implanting into the semiconductor layer at least one species that substantially traps diffusing aluminium.

The forming of the crystalline semiconductor layer on the sapphire substrate may include:
epitaxially growing the crystalline semiconductor layer on the sapphire substrate;
implanting the epitaxially grown layer with at least one species to form a buried amorphous layer of semiconductor under a crystalline layer of semiconductor;
   wherein the at least one species includes the at least one species that substantially traps diffusing aluminium.

The at least one species that substantially traps diffusing aluminium may include at least one of fluorine and hydrogen.

Also described herein is a process for producing a semiconductor-on-sapphire wafer, including:
forming a semiconductor layer on a sapphire substrate; and
forming a buried layer of at least one semiconductor and/or aluminium compound between the sapphire substrate and the semiconductor layer to substantially isolate from the semiconductor layer defects arising from the sapphire-semiconductor interface.

The semiconductor layer formed on the sapphire substrate may be a single-crystal layer including a layer of extended defects caused by the lattice mismatch between the sapphire substrate and the semiconductor layer, and a surface layer of single-crystal and substantially defect-free semiconductor, and the buried layer may be formed from the layer containing the extended defects.

The buried layer may be an amorphous compound that provides stress relief to the surface layer of single-crystal semiconductor. The buried layer may also inhibit diffusion of aluminium from the sapphire substrate into the semiconductor layer.

Also described herein is a process for producing a semiconductor-on-sapphire article, including:

forming a barrier layer and a semiconductor layer on a sapphire substrate, the barrier layer being disposed between the sapphire substrate and the semiconductor layer to inhibit extended defects from forming in the semiconductor layer.

The present invention also provides a semiconductor-on-sapphire article, including:
a sapphire substrate;
a crystalline semiconductor layer; and
a barrier layer disposed between the sapphire substrate and the single-crystal semiconductor layer to inhibit at least one of aluminium from the sapphire substrate and extended defects arising from the sapphire-semiconductor interface from entering the crystalline layer of semiconductor;

wherein the semiconductor is at least one of silicon and a silicon-germanium alloy.

Also described herein is a semiconductor-on-sapphire wafer, including:
a sapphire substrate;
a crystalline semiconductor layer; and
a diffusion barrier disposed between the sapphire substrate and the single-crystal semiconductor layer to inhibit diffusion of aluminium from the sapphire substrate into the crystalline layer of semiconductor.

The diffusion barrier may include a layer of aluminium nitride.

The diffusion barrier may include a layer of at least one oxide of semiconductor.

The diffusion barrier may include a layer containing one or more species that substantially trap diffusing aluminium.

The one or more species may include at least one of fluorine and hydrogen.

Also described herein is a semiconductor-on-sapphire wafer, including:
a semiconductor layer on a sapphire substrate; and
a buried layer of at least one semiconductor and/or aluminium compound disposed between the sapphire substrate and the semiconductor layer to substantially isolate from the semiconductor layer defects arising from the sapphire-semiconductor interface.

The semiconductor layer can be silicon, germanium, or a silicon-germanium alloy, or can consist of multiple layers of at least two of those materials, including silicon-germanium alloys of different compositions.

In some embodiments, a thin aluminium-nitride layer is formed on a cleaned, aluminium-terminated sapphire surface. This layer acts as a barrier to the diffusion of aluminium from the sapphire into the semiconductor, thereby enabling subsequent processing to be performed at high temperatures, including the formation of high-quality semiconductor films. In particular, it enables the formation of semiconductor films using low cost, high throughput deposition techniques.

In some embodiments, molecular beam epitaxy is used to form a thin layer of high quality single-crystal semiconductor directly on the sapphire surface or on a sapphire surface prepared with a thin aluminium-nitride layer, as described in the previous paragraph. With a thin, high quality semiconductor single-crystal seed layer, relatively high quality thick semiconductor layers can be formed by conventional, faster, and lower cost growth techniques, such as vapor phase epitaxy and LPCVD.

In some embodiments, oxygen is implanted into a semiconductor layer formed as described above or by other methods. With a suitable choice of conditions for the implantation and subsequent anneal steps, a multi-layer structure can be formed with a high quality layer of semiconductor dioxide or semiconductor monoxide disposed upon the sapphire substrate and beneath an ultrathin layer of high quality, single crystal semiconductor. The buried oxide layer is formed from a buried region of the semiconductor layer containing defects in the semiconductor lattice structure caused by the lattice mismatch between the sapphire and the semiconductor layer. The formation of the amorphous oxide layer thus removes these defects, provides stress relief to the remaining single-crystal semiconductor surface layer, and also inhibits diffusion of aluminium from the sapphire.

In some embodiments, fluorine, hydrogen or another species is implanted instead of, or in addition to, the semiconductor used to form a buried amorphous layer as described above. The additional species are selected such that they inhibit the diffusion of aluminium into the semiconductor during subsequent high temperature processing steps.

### BRIEF DESCRIPTION OF THE DRAWINGS

Some embodiments of the present invention are hereinafter described, by way of example only, with reference to the accompanying drawings, wherein:

FIG. 1 is a transmission electron microscope image of a cross-section of a prior art SOS device structure showing extended defects in the single-crystal silicon layer caused by the lattice mismatch between the silicon layer and the sapphire substrate;

FIG. 2 is a schematic cross-sectional side view of an SOS structure in accordance with some embodiments of the present invention;

FIGS. 3A to 3C are schematic cross-sectional side views illustrating steps of a process for producing the SOS structure of FIG. 2;

FIG. 4 is a schematic cross-sectional side view of an SOS structure in accordance with other embodiments of the present invention; and

FIGS. 5A and 5B are schematic cross-sectional side views illustrating the steps of a process for producing the SOS structure of FIG. 4.

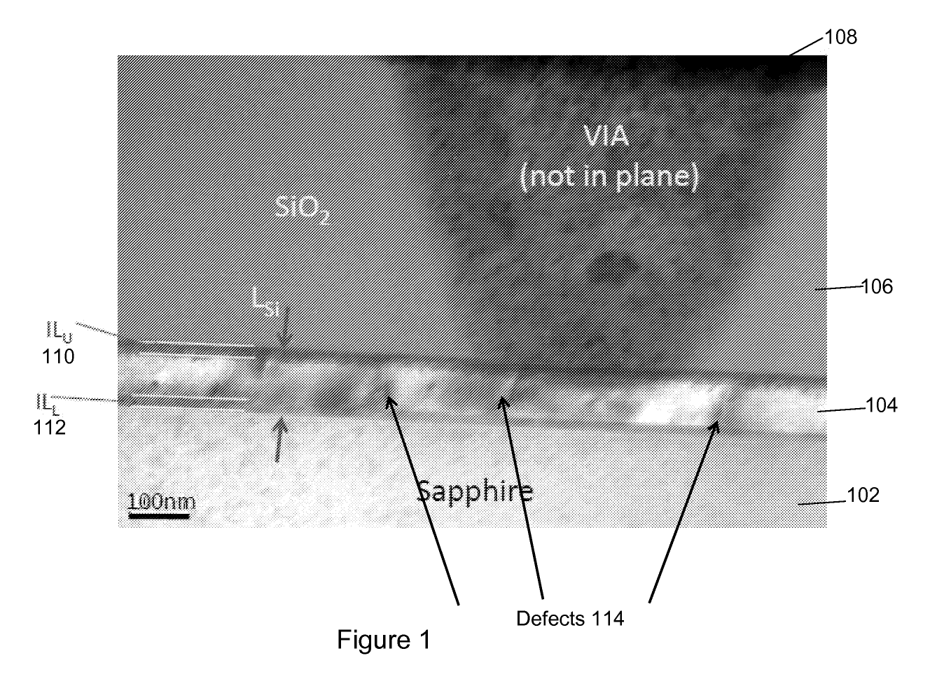

### DETAILED DESCRIPTION

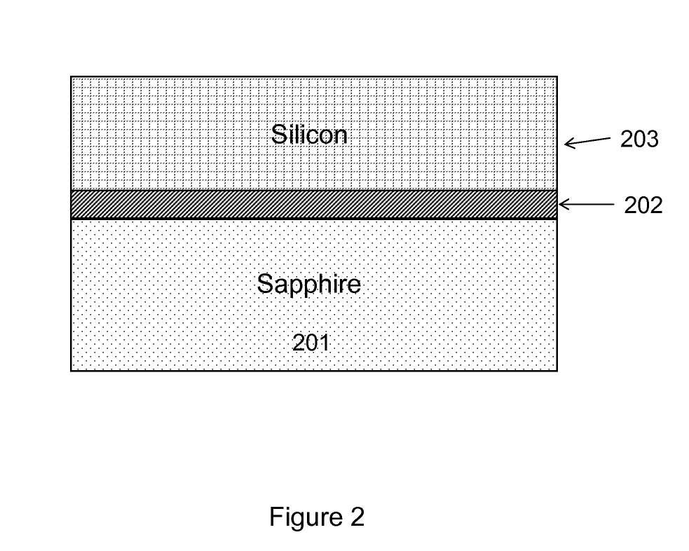

As shown in FIG. 2, a silicon-on-sapphire (SOS) substrate includes a thin layer of silicon 203 on a sapphire support 201. The SOS substrate also includes a barrier layer 202 disposed between the silicon layer 203 and the sapphire 201 to inhibit the diffusion of aluminium from the sapphire 201 into the silicon 203, thereby enabling the use of high temperature processing that in turn enables the silicon thin film 203 to be of a higher quality than would otherwise be possible without the barrier layer 202.

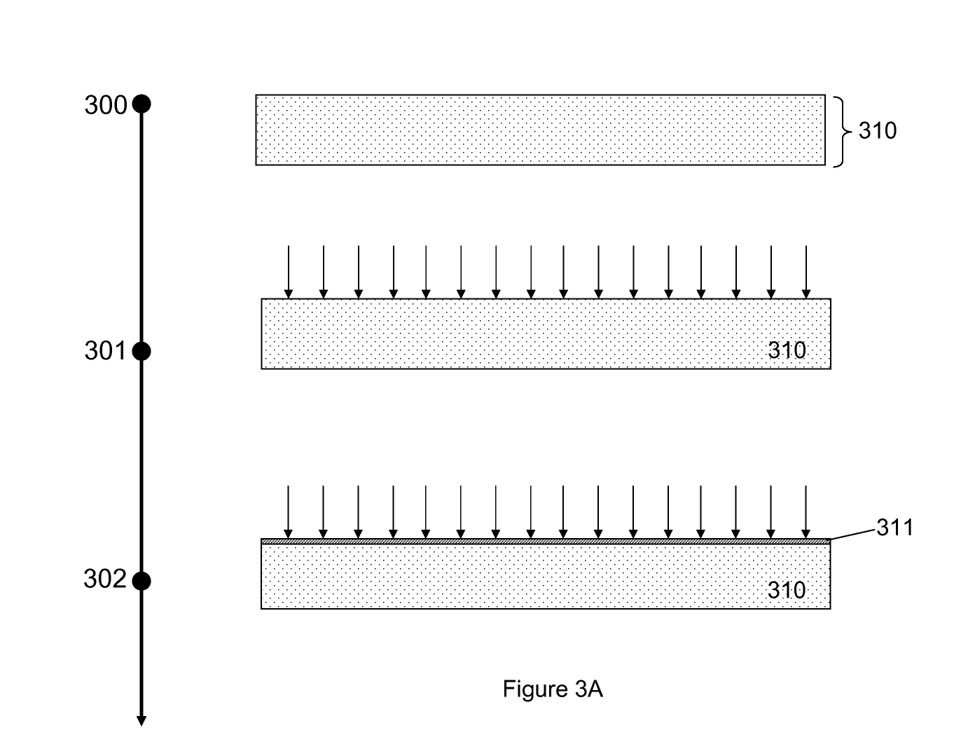

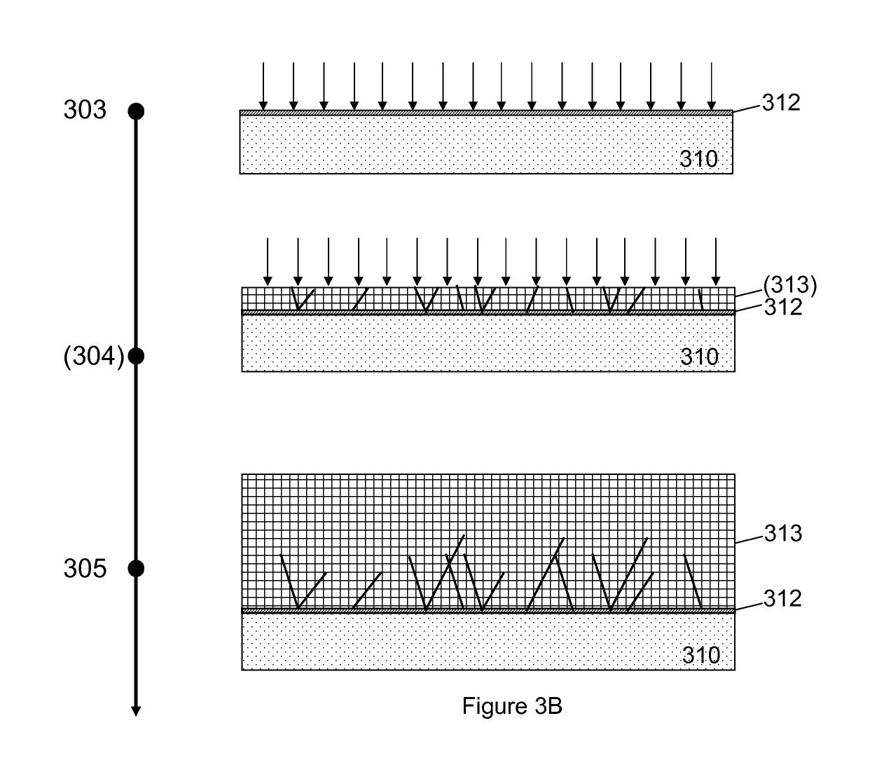

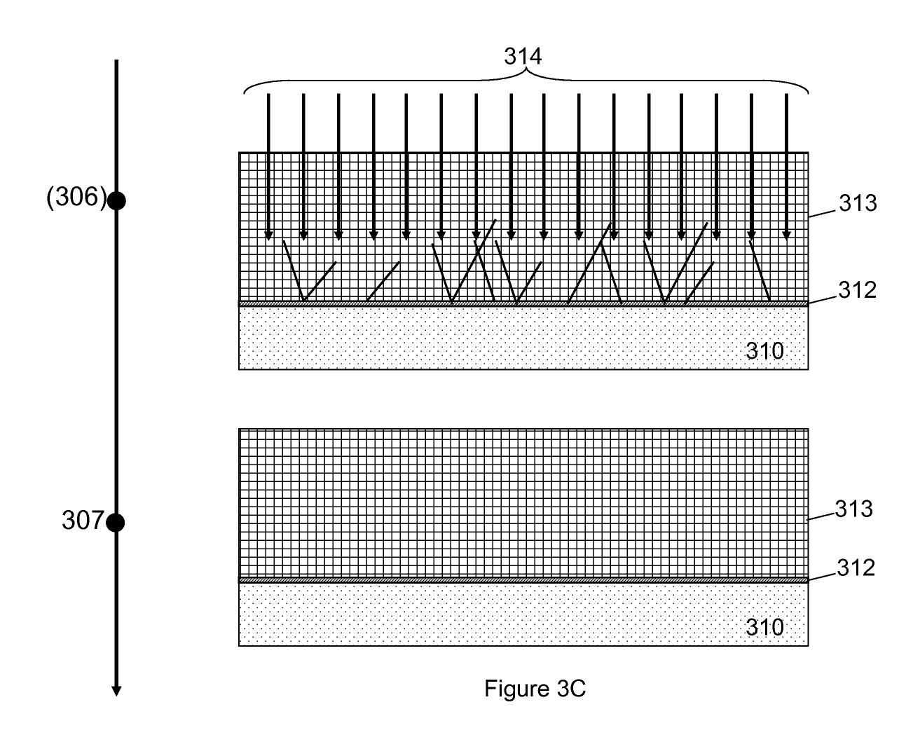

The SOS substrate of FIG. 2 can be formed by a process described below. As shown in FIG. 3, the process begins by cleaning the surface of a sapphire wafer or substrate 310 at step 301, using an oxygen plasma to remove particulate and impurity contamination. At step 302, at least one aluminium monolayer 311 is then deposited to ensure that the sapphire surface is terminated by aluminium. The Al monolayer(s) can be deposited by molecular beam epitaxy (MBE), or by chemical vapour deposition (CVD) under carefully controlled conditions. At step 303, the aluminium-terminated surface is further treated with an active nitrogen species to form an aluminium nitride (AlN) layer 312 on the surface. The thickness of the AlN layer is generally about 1-50 nm, but is typically about 10 nm. For example, the AlN layer 312 can be formed by plasma-enhanced CVD (PECVD).

In other embodiments, the AlN layer 312 is formed by implanting nitrogen ions into the surface of the sapphire substrate and annealing the implanted sapphire to form the layer of AlN 312.

Irrespective of how the barrier layer 312 is formed, it reduces the formation of silicon oxides at the silicon-sapphire interface and reduces the diffusion of aluminium from the sapphire 310, enabling subsequent processing at much higher temperatures than would otherwise be possible without degrading the performance of electronic and/or opto-electronic devices formed on the SOS substrate.

Although the barrier layer is described above as being AlN, alternative embodiments may use other materials, such as silicon oxides, for example, or atomic species such as H or F that inhibit the diffusion of aluminium. Alternatively, a layer of localised extended defects can be used to trap diffusing aluminium; for example, cavities formed by implantation of gaseous species such as hydrogen, as described in, for example, J. S. Williams et. al., Interaction of Defects and Metals with Nanocavities in Silicon, in Nuclear Instruments and Methods in Physics Research B 178 (2001) 33-43, and the references cited therein.

In an optional step 304, a very thin layer of high quality silicon 313 is epitaxially grown on the treated surface. This layer 313 can be grown using molecular beam epitaxy (MBE) 313 to ensure that the grown silicon layer 313 has the highest possible quality. This high quality single-crystal layer 313 acts as a seed layer for further epitaxial growth of silicon, as described below, and can greatly improve the quality of the subsequently grown film.

Irrespective of whether the optional step 304 was included in the process, at step 305, a thicker (e.g., 50-1000 nm, but typically about 300 nm) silicon layer 313 is then formed upon the modified substrate. In some embodiments, the layer 313 is formed using a standard LPCVD process to deposit a layer of polysilicon. In other embodiments, the layer 313 is a single-crystal layer formed by vapor phase epitaxy. However, in any case, the deposition/growth step 305 can use a deposition/growth method that has higher throughput and lower cost than the method (e.g., MBE) used to form the initial high quality single-crystal layer 313 at step 304 (if that step is included).

At optional step 306, a boron implant step 314 is performed to dope the silicon layer 313. In embodiments where the silicon layer 313 is deposited as CVD polysilicon, at step 307, a subsequent high temperature anneal (about 900-1200° C., but typically about 1100° C.) transforms the deposited polysilicon layer into a substantially single crystal silicon layer by epitaxial recrystallisation, either from the underlying high quality silicon layer (if step 304 was included), or otherwise from the sapphire/AlN surface. If the boron implant step 306 is included in the process, the boron doping increases the recrystallisation rate. The high temperature anneal can be performed in a nitrogen or forming gas ambient to passivate surface states.

Thus the use of a diffusion barrier 312 allows the SOS structure to be annealed at high temperatures without substantial diffusion of Al into the silicon layer, thereby allowing silicon layers formed by relatively low cost and/or high throughput deposition methods to be transformed to high-quality single-crystal silicon layers without requiring the complex and costly amorphisation and recrystallisation steps described above.

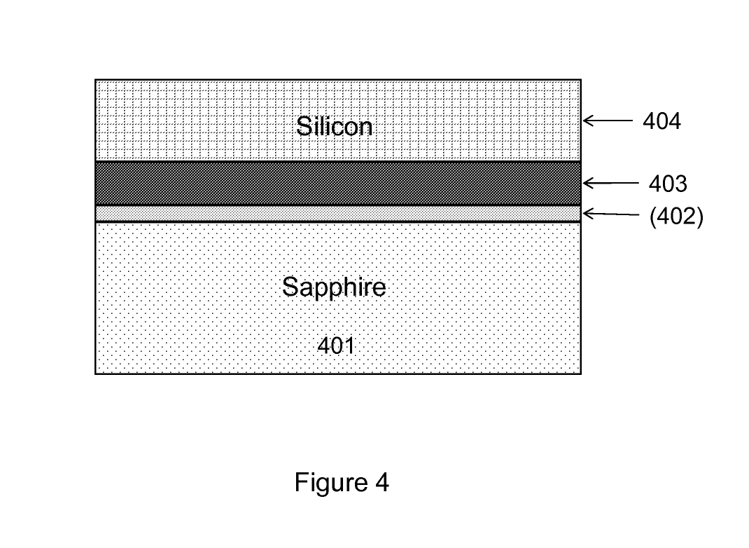

In other embodiments, as shown in FIG. 4, an amorphous and electrically insulating intermediate layer 403 separates a layer of high quality, substantially single crystal silicon thin film 404 from an electrically insulating substrate consisting of a sapphire wafer 401 and an optional buffer or template layer 402. The amorphous intermediate layer 403 can be silicon oxide (SiOₓ), silicon oxynitride (SiₓO_{y}N_{z}), nitrogen-doped silicon oxide (N:SiOₓ), oxygen doped silicon nitride (O:SiₓN_{y}), aluminium nitride (AlN), aluminium oxynitride (AlₓO_{y}N_{z}), nitrogen doped aluminium oxide (N:AlyOz), alumino-silicate (AlxSiyOz), alumino-silicon oxynitride (SixAlyOzNw), silicon aluminium nitride (SixAlyNz), nitrogen doped alumino-silicate (N:SixAlyOz), oxygen-doped alumino-silicon nitride (O:SixAlyNz), and/or combinations of these compounds.

In some embodiments, the intermediate layer 403 is a compound formed by ion implantation of one or more of the compound constituents into the defective portion of an initial silicon layer formed on the sapphire wafer 401 (optionally capped with a barrier layer 402 as described above). The initial silicon layer can be formed by epitaxial growth, polysilicon deposition and anneal, or by some other means. The thickness of the silicon layer can be between about 200 nm and about 10 μm, but is typically about 1 μm. In some embodiments, the implanted species is oxygen and the intermediate layer 403 is silicon dioxide, formed by annealing the wafer after the oxygen implantation. In other embodiments, the implanted species is nitrogen and the intermediate layer 403 is a silicon nitride layer formed on a transition layer 402 of aluminium nitride. The energy and fluence of the implanted species are chosen to provide a sufficient concentration impurity to form the desired compound in the defective region while leaving the surface layer of single crystal silicon substantially intact.

By forming the amorphous and insulating intermediate layer 403 from the defective region of the initial defective silicon layer, the defects are effectively removed and the thickness of the silicon layer is correspondingly reduced. Moreover, the amorphous intermediate layer 403 provides stress relief to the overlying silicon surface layer, thus preventing defects from forming therein. Additionally, the intermediate layer 403 also inhibits diffusion of aluminium from the sapphire substrate 401, thereby allowing the use of high temperature processing steps without substantial diffusion of aluminium into the silicon layer 404.

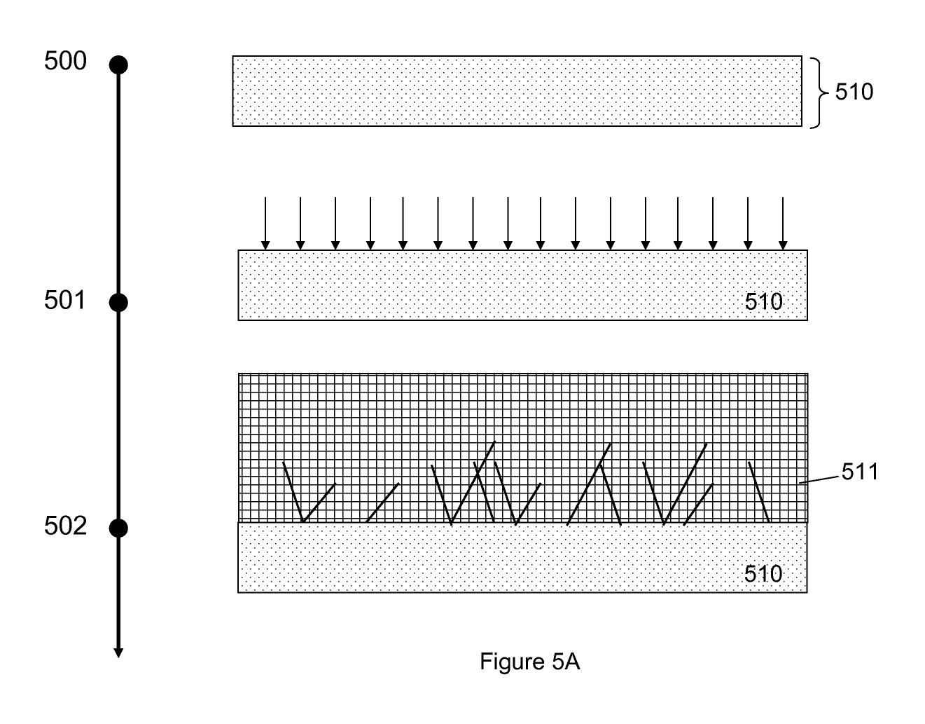

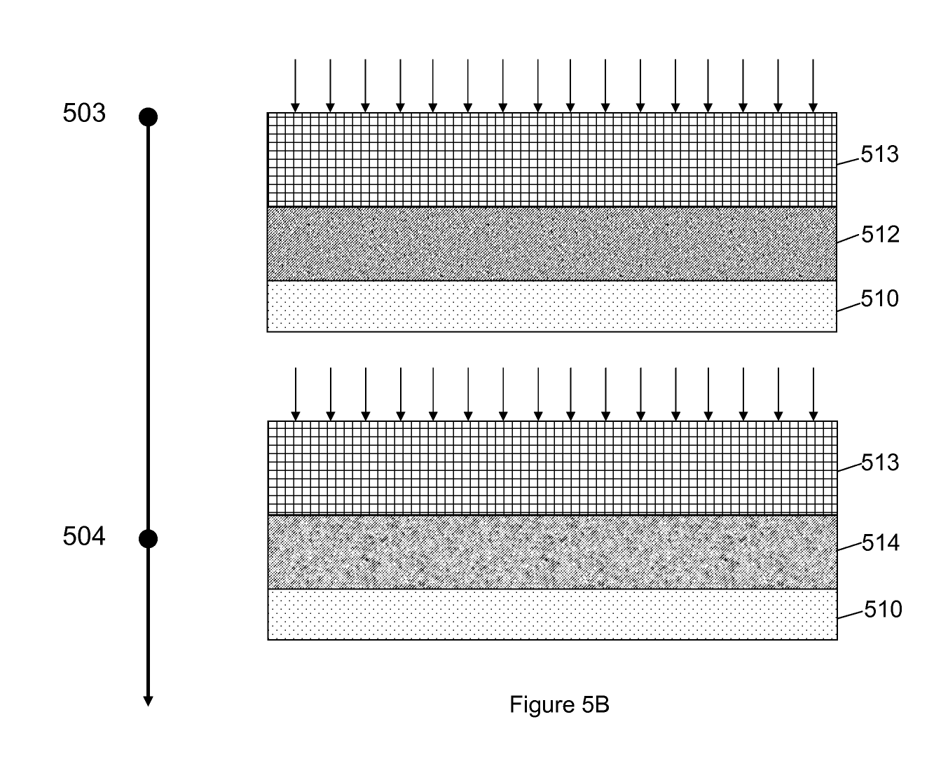

FIGS. 5A and 5B illustrate a two-implant process for forming a buried oxide layer in silicon on sapphire. At step 501, the surface of a sapphire substrate 510 is prepared as described above, with cleaning, optional termination by aluminium or oxygen, and optional deposition of a barrier layer. At step 502, a silicon layer 511 is formed, either directly by epitaxial growth, or by first depositing of polycrystalline silicon in an LPCVD chamber, followed by a high temperature anneal. In an optional step 503, species such as silicon, fluorine, and/or hydrogen ions are implanted into the defective region of the silicon substantially in the vicinity of (and in some cases straddling) the silicon-sapphire interface, serving to amorphize the defective crystal region close to the silicon-sapphire interface. The result is a buried amorphous silicon layer 512 under a single-crystal silicon surface layer 513. At step 504, an additional species, such as oxygen, is implanted to provide a sufficient concentration of atoms to bind with silicon into an insulating layer. If the optional amorphisation step 503 was not included in the process, then the ion energy and fluence of the implant step 504 are also selected to effect the amorphisation described above. Upon thermal activation, the reaction Si+2O→SiO₂ results in the formation of a buried oxide layer 514, as shown in FIG. 5B.

In embodiments where a buried oxide layer 514 is formed, oxygen ions are typically implanted to a fluence in the range of about 1.0×10¹⁷cm⁻² to about 1.5×10¹⁸cm⁻²; however, lower fluences can be selected to reduce unwanted damage to the single crystal silicon surface layer. In any case, the implant conditions are selected to form a continuous layer of high quality silicon dioxide with few if any silicon dioxide precipitates in the silicon layer, and/or silicon precipitates in the oxide layer. The implant energies typically vary from about 100 keV to about 200 keV, depending on the thickness of the initial silicon layer. The energy is typically selected so that the peak of the implanted species is close to the peak density of the silicon defects. Implants are performed at a moderate temperature of 500° C. to 600° C. in order to limit the damage to the single crystal silicon surface layer. A subsequent anneal step repairs damage to the surface crystal and increases the density of the buried oxide layer. The anneal is typically at about 1350° C. and in an argon ambient.

For example, a high quality silicon dioxide layer can be formed in a silicon layer of thickness 200-500 nm by implanting oxygen to a relatively low fluence of about 2×10¹⁷cm⁻² at an energy of about 100 keV. Using a relatively low oxygen fluence can dramatically reduce the implant damage and dislocation density in the topmost Si active layer. A buried layer formed using such a low fluence implant can be as thin as 80 to 100 nm. Buried oxide layers as thin as 65 nm can be formed by reducing the fluence to about 4×10¹⁷cm⁻² and the energy to about 65 keV, followed by a four hour anneal at 1350° C.

In yet further embodiments, the extended defects resulting from the lattice mismatch between the epitaxial silicon and the sapphire surface are substantially removed by implanting the silicon layer to form a buried amorphous layer under a layer of single-crystal silicon. As generally described above, the remaining single crystal silicon surface layer can then act as a seed for the recrystallisation of the amorphous layer during subsequent anneal steps. However, in contrast to prior art methods, fluorine, hydrogen and/or another species is implanted instead of, or in addition to, the silicon ions used exclusively in prior art methods. The additional species is selected such that it inhibits the diffusion of aluminium into the silicon in subsequent anneal steps. For example, both H and F are known to passivate dangling bonds in silicon and their presence has been found to inhibit the diffusion of Al in Si.

Although embodiments of the present invention have been described above in terms of forming layers of silicon on the sapphire substrate, it will be apparent to those skilled in the art that other embodiments of the invention can be applied to forming layers of germanium, silicon-germanium alloys (SiₓGe₁₋ₓ), and/or combinations of either or both of these with one or more silicon layers. Layers of germanium or silicon-germanium alloys can be grown epitaxially as described above, or can alternatively be formed using ion implantation. For example, a silicon-germanium alloy layer can be formed by first forming a silicon layer on the sapphire substrate, implanting germanium into the silicon layer, and annealing the implanted layer to form a layer of silicon-germanium alloy. Depending at least in part on the desired alloy composition, the implantation may be performed to amorphise the implanted layer, and the annealing can then form a single-crystal SiₓGe₁₋ₓ layer by epitaxial regrowth from the sapphire substrate.

Conversely, a layer of germanium can be formed on the sapphire substrate, and silicon ions implanted into the germanium layer, with thermal processing used to regrow the amorphised layer or otherwise anneal the implant damage.

Alternatively, these layers can be formed on one or more existing layers of silicon, germanium, and/or one or more alloys thereof to form multi-layer stacks or superlattices of arbitrary combinations of these materials on a sapphire substrate. The semiconductor layers can include silicon-germanium alloys of different compositions.

In general, the sapphire substrate can be cut or otherwise prepared to have an exposed surface of any one of a variety of different crystal planes, including the R-planes, C-planes, M-planes, and A-planes.

Many modifications will be apparent to those skilled in the art without departing from the scope of the present invention. For example, the methods described above can be used in combination to further improve the properties of the semiconductor layer(s), and thereby improve the performance of opto- and/or electronic devices formed therein.

1. A process for producing a semiconductor-on-sapphire article, including:
forming a barrier layer and a semiconductor layer on a sapphire substrate, the barrier layer being disposed between the sapphire substrate and the semiconductor layer to inhibit at least one of aluminium from the sapphire and extended defects arising from the sapphire-semiconductor interface from entering the semiconductor layer;
wherein the semiconductor is at least one of silicon and a silicon-germanium alloy.

2. The process of claim 1, wherein the forming includes:
forming the barrier layer on the sapphire substrate; and
forming the semiconductor layer on the barrier layer.

3. The process of claim 1, wherein the forming includes:
forming the semiconductor layer on the sapphire substrate; and
forming the barrier layer between the sapphire substrate and the semiconductor layer.

4. The process of claim 1, wherein the semiconductor layer is an epitaxially grown, high-quality single-crystal semiconductor layer.

5. The process of claim 4, including forming, on the high-quality single-crystal semiconductor layer, a further single-crystal semiconductor layer, wherein the barrier layer allows the further single-crystal semiconductor layer to be epitaxially grown at a high temperature to substantially improve the quality of the further single-crystal semiconductor layer without substantial aluminium diffusion from the sapphire substrate into either of the single-crystal semiconductor layers.

6. The process of claim 5, wherein the initial high-quality single-crystal semiconductor layer is formed by molecular beam epitaxy and the further single-crystal semiconductor layer is formed by vapour phase epitaxy or low pressure chemical vapour deposition (LPCVD).

7. The process of claim 1, wherein the barrier layer includes at least one of a compound of semiconductor and a compound of aluminium.

8. The process of claim 7, wherein the barrier layer includes at least one of semiconductor nitride and aluminium nitride.

9. The process of claim 7, wherein the barrier layer includes at least one oxide of semiconductor.

10. The process of claim 1, wherein the forming of the barrier layer includes exposing the sapphire substrate to a reactive plasma.

11. The process of claim 1, wherein the forming of the barrier layer includes ion implantation.

12. The process of claim 11, wherein the semiconductor layer is crystalline, and the ion implantation amorphises a buried portion of the semiconductor layer.

13. The process of claim 11, wherein the forming of the barrier layer includes implanting into the semiconductor layer at least one species that forms traps for diffusing aluminium.

14. The process of claim 13, wherein the traps include internal cavities formed by implanting a gaseous species into the semiconductor layer and subsequent thermal processing.

15. The process of claim 13, wherein the forming of the semiconductor layer includes:
epitaxially growing a crystalline semiconductor layer on the substrate; and
implanting the epitaxially grown layer with at least one species to form a buried amorphous layer of semiconductor under a crystalline layer of semiconductor;
wherein the at least one species includes the at least one species that forms the traps for diffusing aluminium.

16. The process of claim 15, wherein the at least one species that forms traps for diffusing aluminium includes at least one of fluorine and hydrogen.

17. The process of claim 1, wherein the barrier layer inhibits extended defects arising from the sapphire-semiconductor interface from entering the semiconductor layer.

18. The process of claim 17, wherein the semiconductor layer is a substantially single-crystal layer that includes a first layer having a substantially high density of extended defects caused by the lattice mismatch between the sapphire substrate and the semiconductor of the first layer, and a second layer of single-crystal semiconductor substantially free of extended defects, and the barrier layer is formed from the first layer containing the extended defects.

19. The process of claim 18, wherein the barrier layer is an amorphous layer that provides stress relief to the second layer of single-crystal semiconductor.

20. The process of claim 18, wherein the barrier layer also inhibits diffusion of aluminium from the sapphire substrate into the second semiconductor layer.

21. A semiconductor-on-sapphire article, including:
a sapphire substrate;
a crystalline semiconductor layer; and
a barrier layer disposed between the sapphire substrate and the single-crystal semiconductor layer to inhibit at least one of aluminium from the sapphire substrate and extended defects arising from the sapphire-semiconductor interface from entering the crystalline layer of semiconductor;
wherein the semiconductor is at least one of silicon and a silicon-germanium alloy.

22. The article of claim 21, wherein the barrier layer includes a layer of aluminium nitride.

23. The article of claim 21, wherein the barrier layer includes a layer of at least one oxide of semiconductor.

24. The article of claim 21, wherein the barrier layer includes one or more species that form traps that substantially inhibit the diffusion of aluminium.

25. The article of claim 24, wherein the one or more species includes at least one of fluorine and hydrogen.

26. The article of claim 21, wherein the barrier layer includes a layer of amorphous semiconductor.

27. The article of claim 21, wherein the barrier layer inhibits extended defects arising from the sapphire-semiconductor interface from entering the crystalline layer of semiconductor.

28. The article of claim 21, wherein the semiconductor is silicon.

29. The article of claim 21, wherein the semiconductor is a silicon-germanium alloy.

30. The process of claim 1, wherein the semiconductor is silicon.

31. The process of claim 1, wherein the semiconductor is a silicon-germanium alloy.
